(19) United States
(12) Patent Application Publication
(10) Pub. No.: US 2026/0324345 A1
(43) Pub. Date: Oct. 15, 2026

(54) CONTROLLING MOISTURE CONTENT IN EFEM USING LOCALIZED PURGE, DRY AIRFLOW, AND REDUCED SUBSTRATE EXPOSURE TIME TO AIRFLOW

(71) Applicant: ASM IP Holding B.V., Almere (NL)

(72) Inventor: Salam Harb, Scottsdale, AZ (US)

(21) Appl. No.: 19/644,127

(22) Filed: Apr. 10, 2026

Related U.S. Application Data
(60) Provisional application No. 63/789,062, filed on Apr. 15, 2025.

(51) Int. Cl. H10P 72/00; B25J 11/00; H10P 72/76

(52) U.S. Cl. CPC H10P 72/0466; B25J 11/0095; H10P 72/7602

(57) ABSTRACT

Semiconductor device processing apparatuses for controlling exposure of a substrate to moisture are disclosed. One apparatus is configured to flow a gas over a substrate to prevent the absorption of moisture by the substrate. Another apparatus is configured to minimize exposure time of a substrate to an environment with higher relative humidity. Another apparatus is configured to provide dehumidified air to an equipment front-end module.

### CROSS-REFERENCE TO RELATED APPLICATIONS

This application claims priority to U.S. Provisional Patent Application Ser. No. 63/789,062 filed Apr. 15, 2025 titled CONTROLLING MOISTURE CONTENT IN EFEM USING LOCALIZED PURGE, DRY AIRFLOW, AND REDUCED SUBSTRATE EXPOSURE TIME TO AIRFLOW, the disclosure of which is hereby incorporated by reference in its entirety.

### TECHNICAL FIELD

The present disclosure relates generally to the field of semiconductor processing methods and systems and the field of device and integrated circuit manufacture. More particularly the present disclosure generally relates to reducing the exposure of substrates to moisture.

### BACKGROUND

Moisture affects the processing of semiconductor substrates. Once in a process chamber, extra processing steps may be performed to remove moisture from the surface of a substrate. These extra processing steps are often associated with the time required to perform each process. Because of these required moisture-reducing steps, the ability to increase the throughput of semiconductor processing systems may be constrained due to these required moisture-reducing steps.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to reducing moisture on the surfaces of substrates prior to entering process chambers. The reduction of moisture prior to the substrates reaching the process chambers reduces the quantity of and/or time associated with the steps needed to reduce the moisture present on the surfaces of the substrates.

In accordance with examples of the disclosure, an apparatus may comprise a housing defining an interior space, a first gate valve connectable to a first area atmospherically isolated from the interior space, a second gate valve connectable to a second area atmospherically isolated from the interior space, a substrate support plate, a robotic arm configured to move substrates between the first gate valve, the second gate valve, and the substrate support plate, a gas inlet, and a gas outlet. The gas inlet and the gas outlet may be configured to flow gas across the substrate support plate. The gas may comprise nitrogen gas.

In accordance with examples of the disclosure, the apparatus may comprise an equipment front-end module (EFEM) with an enclosed chamber with a pre-aligner device configured to align a received substrate, and a third gate valve connecting the enclosed chamber to the interior space. The substrate support plate may be inside the pre-aligner device. The gas inlet and the gas outlet may be in the enclosed chamber. The robotic arm may move substrates between one or more loading ports accessible via the first gate valve, a load-lock module accessible via the second gate valve, and the enclosed chamber accessible via the third gate valve. The enclosed chamber may flow the gas from the gas inlet toward the gas outlet while the robotic arm transports a substrate through the third gate valve. The gas outlet may be located closer to the third gate valve than the gas inlet. The gas flow direction may be toward the third gate valve. The flow of gas may be referred to as a localized purge and/or as a gas curtain.

In accordance with examples of the disclosure, the apparatus may comprise an equipment front-end module (EFEM) with an enclosed chamber with a heating plate configured to heat a received substrate or a cooling plate configured to cool the received substrate.

In accordance with examples of the disclosure, the apparatus may comprise a load-lock module where the first gate valve is connectable to an equipment front-end module, the second gate valve is connectable to a substrate handling chamber, the gas outlet is located closer to the first gate valve than the gas inlet, and the gas inlet and the gas outlet are configured to flow, toward the first gate valve when the first gate valve is open, the gas across the substrate support plate. The first gate valve may permit a robotic arm, from the equipment front-end module, access to the substrate support plate. The second gate valve may permit a robotic arm, from the substrate handling chamber, access to the substrate support plate.

In accordance with examples of the disclosure, an equipment front-end module may comprise a first gate valve connectable to one or more loading ports, a second gate valve connectable to a load-lock module, a pre-aligner device configured to align substrates, the pre-aligner device comprises a third gate valve, a garage configured to temporarily hold a substrate, the garage comprises a fourth gate valve, a robotic arm configured to move substrates between the one or more loading ports and the load-lock module, and a controller configured to delay the opening of the gate valves until the pre-aligner device, garage, or load-lock module is ready to receive a substrate and the robotic arm is available.

In accordance with examples of the disclosure, the controller may determine whether the robotic arm is available, determine, based on the robotic arm being available, whether the pre-aligner device is available, open, based on the pre-aligner device being available, the first gate valve and the third gate valve, move a substrate from a loading port to the pre-aligner device, and close the first gate valve and the third gate valve. In accordance with examples of the disclosure, the controller may determine whether the robotic arm is available, determine, based on the robotic arm being available, whether the load-lock module is available, open, based on the load-lock being available, the second gate valve and one of the third gate valve or the fourth gate valve, move a substrate from the pre-aligner device or the garage to the load-lock module, and close the second gate valve and the open one of the third gate valve or the fourth gate valve. In accordance with examples of the disclosure, the controller may determine whether the robotic arm is available, determine, based on the robotic arm being available, whether the garage is available, open, based on the garage being available, the fourth gate valve and one of the second gate valve or the third gate valve, move a substrate from the pre-aligner device or the load-lock module to the garage, and close the fourth gate valve and the open one of the second gate valve or the third gate valve. In accordance with examples of the disclosure, the controller may determine whether the robotic arm is available, determine, based on the robotic arm being available, whether a loading port is available, open, based on the loading port being available, the first gate valve and one of the second gate valve or the fourth gate valve, move a substrate from the garage or the load-lock module to the loading port, and close the first gate valve and the open one of the second gate valve or the fourth gate valve. A result includes reducing the substrate's exposure time to airflow with moisture.

In accordance with examples of the disclosure, an equipment front-end module may comprise a first gate valve connectable to one or more loading ports, a second gate valve connectable to a load-lock module, a first robotic arm configured to move substrates between the one or more loading ports and the load-lock module, an air intake, a dehumidifier comprising an inlet configured to receive ambient air external to the equipment front-end module and an outlet, and a fan configured to move dehumidified air from the dehumidifier outlet to the air intake. The equipment front-end module may include a fan filter unit, located between the fan and the air intake, configured to filter the dehumidified air. The dehumidifier may be a multi-stage dehumidifier comprising cooling coils and a descant wheel. The dehumidified air may have a percent relative humidity of less than 0.6% (i.e., dryer than the ambient air outside of the EFEM).

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a semiconductor processing system in accordance with one or more embodiments of the disclosure.

FIG. 2 illustrates a gas-flowing system in a semiconductor processing system with a gas inlet and gas outlet in accordance with one or more embodiments of the disclosure.

FIG. 3 illustrates specific chambers in a semiconductor processing system with gas inlets and gas outlets in accordance with one or more embodiments of the disclosure.

FIG. 4 illustrates a flowchart for reducing the exposure time of substrates when moving between locations in an equipment front-end module in accordance with one or more embodiments of the disclosure.

FIG. 5 illustrates a table showing a degree of absorption moisture based on exposure time in environments of different relative humidity in accordance with one or more embodiments of the disclosure.

FIG. 6 illustrates an equipment front-end module with a dehumidifier in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, the recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. The substrate can include various topologies, such as gaps, including recesses, lines, trenches or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material.

A substrate may be formed from semiconductor materials, including, for example, silicon (Si), silicon-germanium (SiGe), silicon oxide (SiO2), gallium arsenide (GaAs), gallium nitride (GaN) and silicon carbide (SiC). A substrate may include a pattern or may be unpatterned, such as a so-called blanket-type substrate. For example, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators), or components of photovoltaic cells, etc.

A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for the manufacture and output of the continuous substrate in any appropriate form. Non-limiting examples of continuous substrates may include sheets, non-woven films, rolls, foils, webs, flexible materials, and bundles of continuous filaments or fibers (for example, ceramic fibers or polymer fibers). A continuous substrate may also comprise a carrier or sheet upon which one or more non-continuous substrate is mounted.

As used herein, the term “layer” can refer to any continuous or non-continuous structure and material. For example, a layer can include two-dimensional materials, three-dimensional materials, nanoparticles, or even partial or full molecular layers or partial or full atomic layers or clusters of atoms and/or molecules. A layer may comprise a material or a layer with pinholes, which may be at least partially continuous.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to an average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film, or layer may be directly on the mentioned layer, or another layer (an intermediate layer) or element may be intervened therebetween, or a layer may be disposed on a mentioned layer but not completely cover the surface of the mentioned layer. Therefore, unless the term “directly” is separately used, the term “on” or “over” will be construed to be a relative concept. Similarly to this, it will be understood the terms “under”, “underlying”, or “below” will be construed to be relative concepts.

In the following description of the various embodiments, reference is made to the accompanying drawings, which form a part hereof, and which are shown by way of illustration of various embodiments in which aspects of the disclosure may be practiced. It is to be understood that other embodiments may be utilized and structural and functional modifications may be made without departing from the scope of the present disclosure. Any sequence of computer-implementable instructions described in this disclosure may be considered to be an “algorithm” as those instructions are intended to solve one or more classes of problems or to perform one or more computations. While various directional arrows are shown in the figures of this disclosure, the directional arrows are not intended to be limiting to the extent that bi-directional communications are excluded. Rather, the directional arrows are to show a general flow of steps and not the unidirectional movement of information. Throughout the specification, the expressions “at least one of a, b, and c” and “one or more of a, b, and c” may include ‘a only’, ‘b only’, ‘c only’, ‘a and b’, ‘a and c’, ‘b and c’, and/or ‘all of a, b, and c’.

It is noted that various connections between elements are discussed in the following description. It is noted that these connections are general and, unless specified otherwise, may be direct or indirect, and that the specification is not intended to be limiting in this respect. As described herein, thresholds are referred to as being “satisfied” to generally encompass situations involving thresholds above increasing values as well as encompass situations involving thresholds below decreasing values. The term “satisfied” is used with thresholds to address when values have passed a threshold and then approaching the threshold from an opposite side using terms such as “greater than”, “greater than or equal to”, “less than”, and “less than or equal to” can add ambiguity where a value repeatedly crosses a threshold.

Moisture from an environment may accumulate on a substrate. One or more aspects relate to reducing moisture on a substrate prior to performing one or more semiconductor processes. The process for reducing moisture may include a localized nitrogen gas curtain or flow when passing a substrate through a gate valve. Where the substrate may sit at a location for a time (e.g., in a pre-aligner device, in a heating garage, in a cooling garage, or being pasted through a load-lock module), reducing the moisture in the environment may help reduce moisture from accumulating on the substrate. Additionally or alternatively, the process for reducing moisture may include reducing movement time between different locations. Reducing movement time may include delaying the start of the individual movement operations until each is ready. Additionally or alternatively, the process for reducing moisture may include modifying the humidity of air provided to an EFEM. EFEMs conventionally obtain air from an environment with an average relative humidity. One or more aspects to reduce moisture in an EFEM is to remove moisture from the air prior to being supplied to an EFEM.

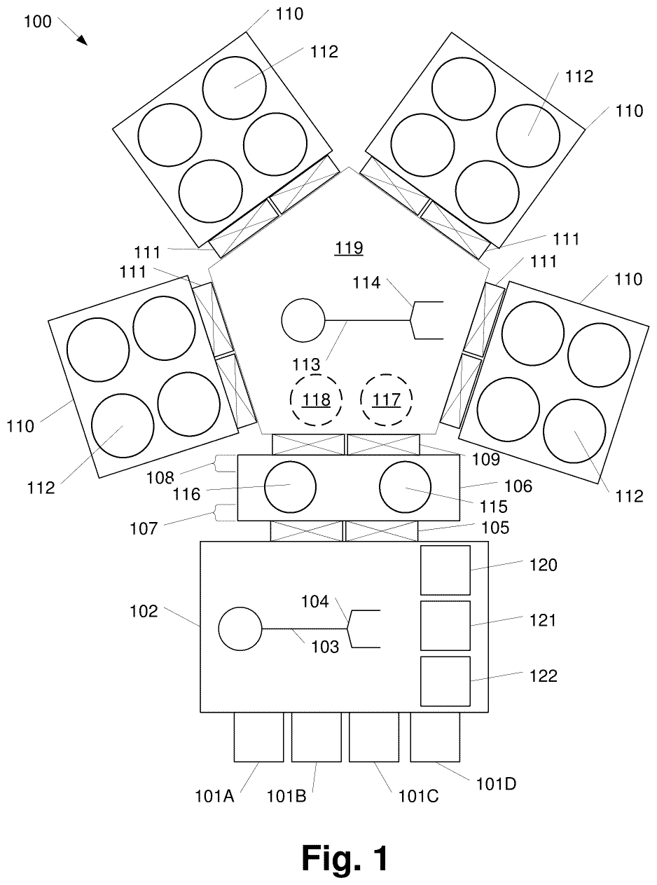

Turning now to the figures, FIG. 1 shows an example of a system with process modules, a substrate handling chamber, and a load lock. In various examples, one or more heater plates may be present in one, two, or multiple of these structures. By having the heater plate in a given structure, the time consumed by downstream systems needing to subsequently heat a wafer to equalize the temperature across the wafer is reduced. FIG. 1 includes an equipment front-end module 102 with a robotic arm 103 having an end effector 104. The robotic arm 103 is configured to move semiconductor wafers between loading ports 101A, 101B, 101C, and 101D and a load-lock module 106. Load-lock module 106 includes one or more semiconductor holding locations 115 and/or 116 to temporarily support a semiconductor wafer while the atmosphere in the load-lock module 106 is being adjusted. Also, one or more semiconductor holding locations 115 and/or 116 may include the heater plate described herein with the different emissivities to heat the wafer to a desired temperature. Similarly, the semiconductor wafer may be cooled at one or more of the semiconductor holding locations 115 and/or 116 by actively cooling the holding locations 115 or 116 or by allowing the wafers to cool as a temperature in the load-lock module 106 drops reduced or via a combination of these approaches.

The load-lock module 106 is connected at one edge or facet of a substrate handling chamber 119. The substrate handling chamber 119 may include or connect with a nitrogen gas source for providing a nitrogen gas atmosphere within the equipment front-end module 102. The equipment front-end module 102 receives new substrates for processing into the substrate processing system 100 and discharges processed substrates from the substrate processing system 100 via one or more loading ports 101A-101D (moving the substrates between the loading port(s) 101A-101D and the load-lock module 106 using the robotic arm 103). While four loading ports 101A-101D are shown in the example of FIG. 1, more or fewer loading ports may be provided in other examples of this technology.

The substrate handling chamber 119 is connected with multiple process modules 110. Wafers are transferred into the process modules 110 where one or more layers of material are deposited onto a surface of the substrate and/or other desired substrate processing takes place. FIG. 1 shows each process module 110 including four substrate supports 112 onto which substrates can be placed during processing. More or fewer substrate supports 112 may be provided in each process module 110 (e.g., the process modules 110 may be dual-chamber modules (DCM) or quad chamber modules (QCM)). Substrate processing modules 110 in accordance with some examples of this technology may include another four substrate supports 112 located vertically beneath the four substrate supports 112 shown in the top view of FIG. 1. Each of the process modules 110 may have the same structures or one or more of the process modules 110 may have a different structure from other process modules 110 present. The substrate handling chamber 119 may also include one or more substrate supports 117/118 (two are shown in FIG. 1). The substrate supports may include a heater plate as described above. Further, one or more of the substrate supports 112 in the process modules 110 may be a heater plate as described herein.

The substrate handling chamber 119 is connected with its respective process modules 110 via one or more gate valves 111. While two gate valves 111 are shown connecting substrate handling chamber 119 with process modules 110, more or fewer gate valves 111 may be provided for each process module 110. Substrate processing modules 110 in accordance with some examples of this technology may be connected with the substrate handling chamber 119 by another two gate valves 111, e.g., located vertically beneath the two gate valves 111 shown in the top view of FIG. 1. When closed, the gate valves 111 sealingly separate the substrate handling chamber 119 the process modules 110 (so that independent atmospheric conditions may be maintained in each chamber). When open, the gate valves 111 provide an opening (e.g., a substrate transfer slot) through which the end effector 114 of a robotic arm 113 can extend to move substrates into and out of the process module 110. The openings through the gate valves 111 align with substrate transfer slots provided in the process modules 110 and the substrate handling chamber 119 to enable substrates to be moved between the process modules 110 and the substrate handling chamber 119 through the gate valves 111. Each of the gate valves 111 may have the same structures or one or more of the gate valves 111 may have a different structure from other gate valves 111 present.

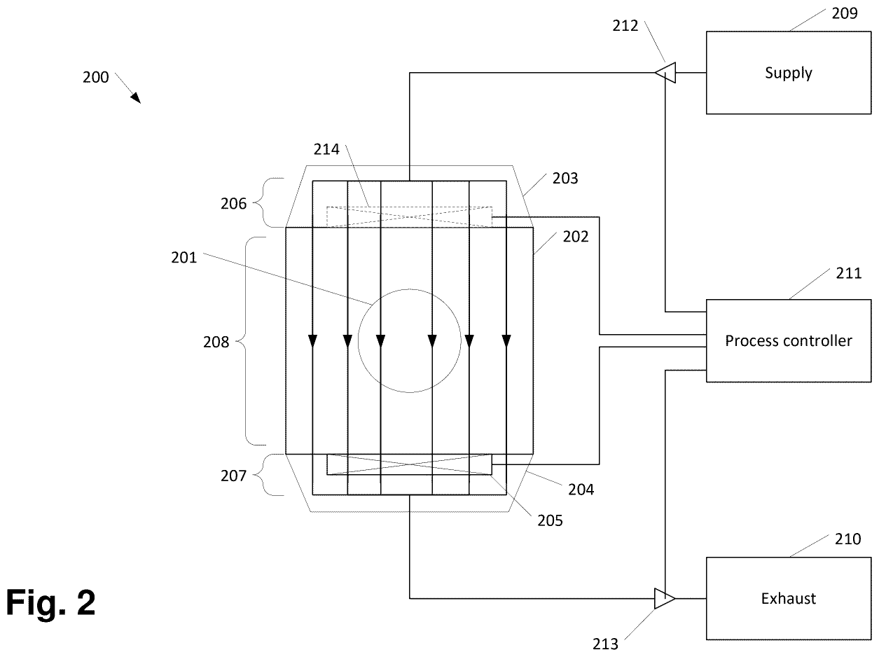

One face 107 of the load-lock module 106 connects with the equipment front-end module 102 by one or more gate valves 105 (two are shown in FIG. 2), and the opposite face 108 of the load-lock module 106 connects with the substrate handling chamber 119 by one or more gate valves 109. The load-lock module 106 further includes one or more substrate supports 115/116 (two are shown in FIG. 1) for holding substrates while they wait to be moved into the equipment front-end module 102 or the substrate handling chamber 119. When closed, the gate valves 105, 109 sealingly separate the load-lock module 106 from the equipment front-end module 102 and the substrate handling chamber 119 (so that independent atmospheric conditions may be maintained in each chamber). When open, the gate valves 105 provide an opening (e.g., a substrate transfer slot) through which the end effector 104 of the robotic arm 103 can extend to move substrates into and out of the equipment front-end module 102. The openings through the gate valves 105 align with substrate transfer slots provided in the equipment front-end module 102 and the load-lock module 106 to enable substrates to be moved between the equipment front-end module 102 and the load-lock module 106 through gate valves 105. When open, the gate valves 109 provide an opening (e.g., a substrate transfer slot) through which the end effector 114 of robotic arm 113 can extend to move substrates into and out of the substrate handling chamber 119. The openings through the gate valves 109 align with substrate transfer slots provided in the substrate handling chamber 119 and the load-lock module 106 to enable substrates to be moved between the substrate handling chamber 119 and the load-lock module 106 through gate valves 109. Each of gate valves 105, 109 may have the same structure or one or more of the gate valves 105, 109 may have a different structure from other gate valves 105, 109.

Process modules 110 may include various equipment to perform semiconductor processing operations including but not limited to chemical vapor deposition, atomic layer deposition, lithography, etching, epitaxial growth, and other operations.

FIG. 2 illustrates a gas-flowing system 200 in a semiconductor processing system with a gas inlet and gas outlet in accordance with one or more embodiments of the disclosure. The gas-flowing system 200 includes a chamber 202 with a gas inlet 203 and a gas outlet 204. A gate valve 205 is located between the chamber 202 and an environment of an equipment front-end module (EFEM). The gas inlet 203 may include a manifold 206 to direct a gas to flow over a substrate 201. The gas outlet 204 may include a manifold 207 to receive the gas flowing over the substrate 201. The gas flowing over the substrate 201 is shown by arrows 208 flowing from the gas inlet 203 to the gas outlet 204 and in a direction toward the gate valve 205.

The gas-flowing system 200 further includes a gas supply 209. The gas supply may comprise one or more containers and valves (as needed) to provide a supply of a gas to the gas-flowing system 200. The gas supply 209 may be connected to one or more valves 212 that regulate the flow of the gas to the gas inlet 203. The one or more valves 212 may be controlled by a process controller 211. The one or more valves 212 may be controlled valves. Additionally or alternatively, the one or more valves 212 may also include one or more pumps to force the gas from supply 209 to the gas inlet 203.

The gas-flowing system 200 further includes a gas exhaust 210. The gas supply may comprise one or more containers and valves (as needed) to receive the gas flowed across the substrate 201. The gas exhaust 210 may be connected to one or more valves 213 that regulate the flow of the gas from the gas outlet 204 to the gas exhaust 210. The one or more valves 213 may be controlled by the process controller 211. The one or more valves 213 may be controlled valves. Additionally or alternatively, the one or more valves 213 may also include one or more pumps to force the gas from gas outlet 204 to the gas exhaust 210.

The process controller 211 may include one or more processors and memory storing instructions that, when executed by the one or more processors, cause the processors to start, stop, and/or regulate the flow of gas from the gas supply 209 to the gas inlet 203 and from the gas outlet 204 to the gas exhaust 210.

The chamber 202 may be enclosed in the EFEM or may be connected to the EFEM. For instance, the chamber 202 may be a pre-aligner device inside an EFEM and configured to align a wafer prior to subsequent processing. Additionally or alternatively, the chamber 202 may be a garage with a heating plate and/or a cooling plate, where the garage is configured to adjust the temperature of a wafer before or after semiconductor device processing. Additionally or alternatively, the chamber 202 may comprise a load-lock module. The chamber 202 may optionally include a gate valve 214 located on an opposite side of the chamber 202 from the gate valve 205. The process controller 211 may also control the opening and closing of gate valve 205 and, if present, the gate valve 214.

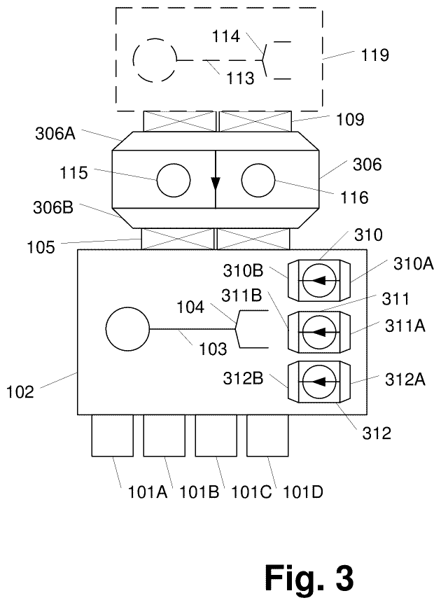

FIG. 3 illustrates specific chambers in a semiconductor processing system with gas inlets and gas outlets in accordance with one or more embodiments of the disclosure. FIG. 3 includes components described with respect to FIG. 1 including the loading ports 101A, 101B, 101C, and 101D, the EFEM 102, the robotic arm 103 with the end effector 104, the gate valves 105 and 109, and the substrate handling chamber 119 with the robotic arm 113 with the end effector 114.

FIG. 3 further includes a load-lock module 306 with a gas inlet 306A and a gas outlet 306B. Gas flowed through the load-lock module 306 flows in a direction from the gate valve 109 toward the gate valve 105 when gate valve 105 is open. FIG. 3 includes a garage 310 with a heater plate configured to heat a substrate prior to loading into a load-lock module 306. The garage 310 includes a gas inlet 310A and a gas outlet 310B configured to flow a gas across a substrate during insertion into the garage 310. FIG. 3 includes a garage 311 with a cooling plate configured to cool a heated substrate received from the load-lock module 306. The garage 311 includes a gas inlet 311A and a gas outlet 311B configured to flow a gas across a substrate during insertion into the garage 311. FIG. 3 includes a garage 312 with a pre-aligner device configured to align a substrate received from a loading port 101A-101D before the substrate is transported to the garage 310 for heating and/or the load-lock module 306. The pre-aligner device 312 includes a gas inlet 312A and a gas outlet 312B configured to flow a gas across a substrate during insertion into the pre-aligner device 312.

The load-lock module 306 includes one or more semiconductor holding locations 115 and/or 116 to temporarily support a semiconductor wafer while the atmosphere in the load-lock module 106 is being adjusted. Also, the one or more semiconductor holding locations 115 and/or 116 may include a heater plate to heat the wafer to a desired temperature. Similarly, the semiconductor wafer may be cooled at one or more of the semiconductor holding locations 115 and/or 116 by actively cooling the holding locations 115 or 116 or by allowing the wafers to cool as a temperature in the load-lock module 306 drops, is reduced, or via a combination of these approaches.

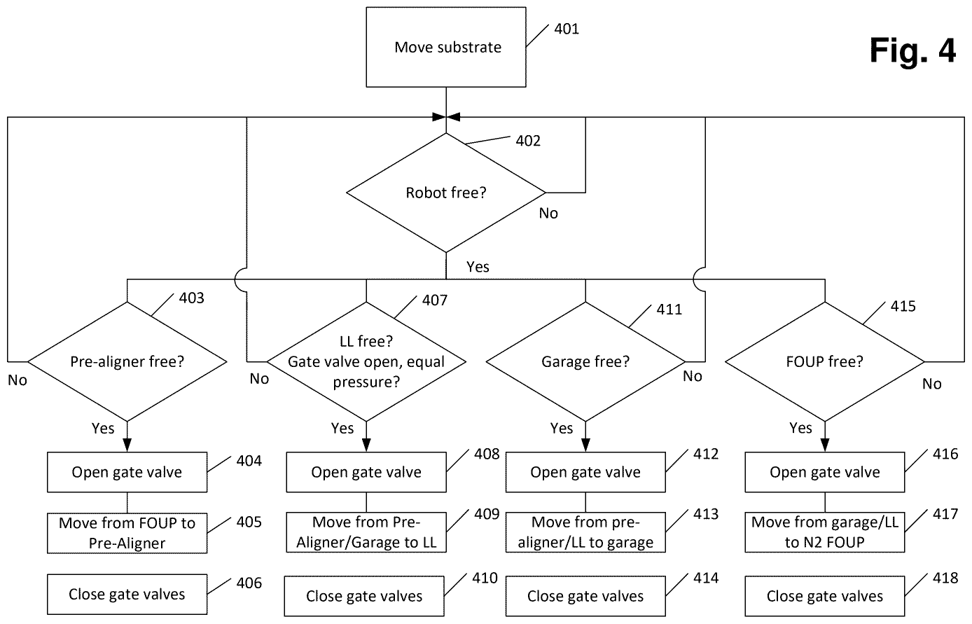

FIG. 4 illustrates a flowchart for reducing exposure time of substrates, when moving between locations in an equipment front-end module, in accordance with one or more embodiments of the disclosure. In step 401, an instruction is received to move a substrate. The instruction 401 may include moving a substrate from a first location behind first gate valves to a second location behind second gate valves. A robotic arm may move the substrate. In step 402, a controller determines whether a robotic arm is available. If the robotic arm is not available, the processor continues to check whether the robotic arm is available before proceeding. Once the robotic arm is available, the controller determines whether the receiving location is ready to receive the substrate. The receiving location may include a pre-aligner device, a load-lock module, a garage for heating or cooling, or a front-opening unified pod (FOUP) is available.

For example, if the destination is the pre-aligner device, the controller determines, in step 403, whether the pre-aligner device is available (e.g., gate valve open). If the pre-aligner device is not available, the controller returns to step 402. If the pre-aligner device is available (from step 403), then the controller opens the gate valve (for a FOUP with the substrate) and for the pre-aligner device) in step 404, controls the robotic arm to move the substrate in step 405, and closes the gate valves in step 406 after the substrate has been moved.

If the destination is the load-lock module, the controller determines, in step 407, whether the load-lock module is available (for instance, is the load-lock module's gate valve open and pressure equalized with that of the EFEM). If the load-lock module is not available, the controller returns to step 402. If the load-lock module (from step 407), then the controller opens the gate valve (for the pre-aligner device, FOUP, or heating garage with the substrate) in step 408, controls the robotic arm to move the substrate in step 409, and closes the gate valves in step 410 after the substrate has been moved.

If the destination is the garage, the controller determines, in step 411, whether the garage is available (e.g., gate valve open). If the garage is not available, the controller returns to step 402. If the garage is available (from step 411), then the controller opens the gate valve (for the pre-aligner device, FOUP, or the load-lock module) in step 412, controls the robotic arm to move the substrate in step 413, and closes the gate valves in step 414 after the substrate has been moved.

If the destination is the FOUP, the controller determines, in step 415, whether the FOUP is available. If the FOUP is not available, the controller returns to step 402. If the FOUP is available (from step 415), then the controller opens the gate valve (for the pre-aligner device, the garage, or the load-lock module) in step 416, controls the robotic arm to move the substrate in step 417, and closes the gate valves in step 418 after the substrate has been moved.

As shown in FIG. 4, the controller waits until both the robotic arm and the destination for the substrate are available before opening the gate valve for the current location of the substrate. By waiting until the robotic arm and destination are available, the time the substrate is exposed to air with humidity may be decreased.

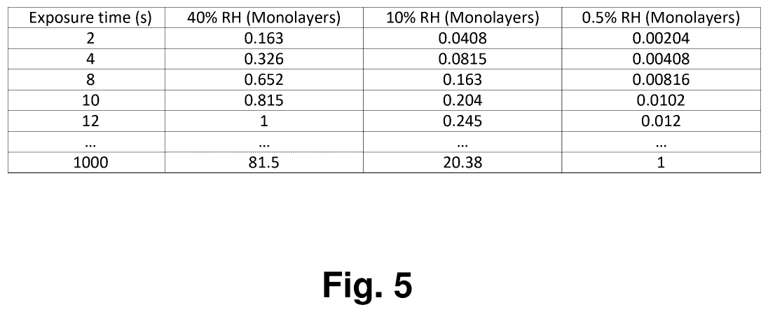

FIG. 5 illustrates a table showing a degree of desorption of moisture based on exposure time in environments of different relative humidity in accordance with one or more embodiments of the disclosure. Where an airflow in an EFEM is 1800 m³/hour at room temperature, the moisture adsorption coefficient of Si wafer is 0.1 (10% of air content). The table of FIG. 5 shows the rates of absorption of water from air with 40% relative humidity (RH), 10% RH, and 0.5% RH. The wafer exposure times are 2, 4, 8 10, 12, and 1000 seconds. The goal is to determine the amount of moisture desorbed at the wafer surface exposed to EFEM. The moisture desorption is calculated in terms of monolayers. Decreasing the time a substrate spends in a higher RH environment reduces how much water is absorbed by a substrate. Also, decreasing the relative humidity reduces how much water is absorbed by a substrate. With respect to FIG. 4, by decreasing the exposure of a substrate to an environment with a higher RH, the RH of the environment may be maintained while decreasing the water absorbed by the substrate. In other words, moving the substrate while minimizing the time spent in the higher RH environment has the effect of moving the substrate more slowly in an environment with a lower RH. To minimize costs, keeping a substrate out of an environment with a higher RH may be as effective as including more components to reduce the higher RH to a lower level.

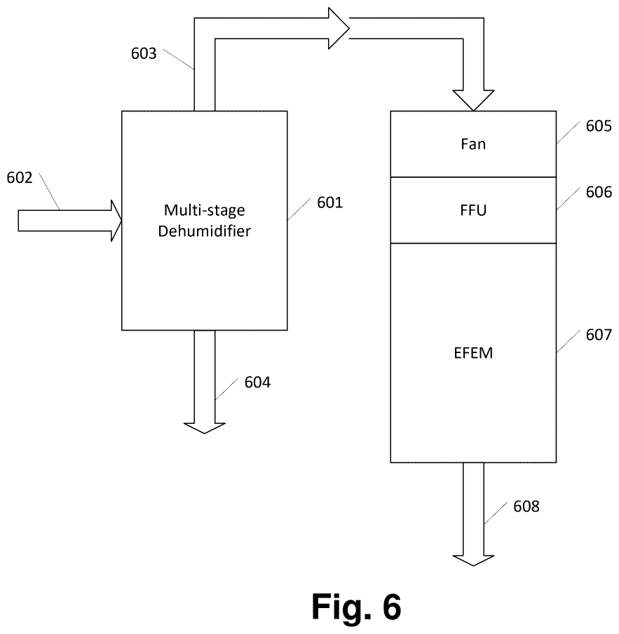

Air Quality ISO 8573.1:2010 specifies classes for water content. Class 2 is specified as 0.58% RH, a pressure dewpoint of −40 °C, a water content of 0.07 g/Kg and 0.17 g/m³, and a moisture content of 55 PPM. Air Quality ISO 8573.1:2010 is hereby incorporated by reference for all air quality classes for all purposes. An EFEM generally receives air from a clean room in which the EFEM is located. Clean rooms are generally at class 4 (e.g., at 23 °C and 40% RH, the water content is 8.83 g/Kg (6900 PPM)). One may specify a process in a process module to have air at Class 2 or better—e.g., a water content of <0.07 g/Kg (55 PPM). FIG. 6 provides an arrangement to reduce the water content of air entering the EFEM.

FIG. 6 illustrates an equipment front-end module with a dehumidifier in accordance with one or more embodiments of the disclosure. Air in a clean room (typically, 23 °C and 40% RH) enters (via air intake 602) a multi-stage dehumidifier 601. Water is discharged from the dehumidifier as water 604. The dehumidified air is output as shown by arrow 603. A fan 605 forces the dehumidified air through a fan filter unit (FFU) 606. The FFU includes a filter and fan for cleaning air to be received by an EFEM 607. Dry air from the dehumidifier may be forced at 1060 CFM at less than 0.6% RH. The EFEM may operate with dry air of less than 0.6% compared to a conventional EFEM operating with air at 40% RH. The multi-stage dehumidifier 601 may include cooling coils and a descant wheel to reduce the RH of air being provided to the fan 605. An example of a multi-stage dehumidifier may include a MiniPAC MP-1200 from the Bry-Air Inc. of Sunbury, Ohio. Other dehumidifiers may be used to provide a RH of less than 0.6%.

In accordance with examples of the disclosure, an apparatus may comprise a housing defining an interior space, a first gate valve connectable to a first area atmospherically isolated from the interior space, a second gate valve connectable to a second area atmospherically isolated from the interior space, a substrate support plate, a robotic arm configured to move substrates between the first gate valve, the second gate valve, and the substrate support plate, a gas inlet, and a gas outlet. The gas inlet and the gas outlet may be configured to flow a gas across the substrate support plate. The gas may comprise nitrogen gas.

In accordance with examples of the disclosure, the apparatus may comprise an equipment front-end module (EFEM) with an enclosed chamber with a pre-aligner device configured to align a received substrate, and a third gate valve connecting the enclosed chamber to the interior space. The substrate support plate may be inside the pre-aligner device. The gas inlet and the gas outlet may be in the enclosed chamber. The robotic arm may move substrates between one or more loading ports accessible via the first gate valve, a load-lock module accessible via the second gate valve, and the enclosed chamber accessible via the third gate valve. The enclosed chamber may flow the gas from the gas inlet toward the gas outlet while the robotic arm transports a substrate through the third gate valve. The gas outlet may be located closer to the third gate valve than the gas inlet. The gas flow direction may be toward the third gate valve.

In accordance with examples of the disclosure, the apparatus may comprise an equipment front-end module (EFEM) with an enclosed chamber with a heating plate configured to heat a received substrate or a cooling plate configured to cool the received substrate.

In accordance with examples of the disclosure, the apparatus may comprise a load-lock module where the first gate valve is connectable to an equipment front-end module, the second gate valve is connectable to a substrate handling chamber, the gas outlet is located closer to the first gate valve than the gas inlet, and the gas inlet and the gas outlet are configured to flow, toward the first gate valve when the first gate valve is open, the gas across the substrate support plate. The first gate valve may permit a robotic arm, from the equipment front-end module, access to the substrate support plate. The second gate valve may permit a robotic arm, from the substrate handling chamber, access to the substrate support plate.

In accordance with examples of the disclosure, an equipment front-end module may comprise a first gate valve connectable to one or more loading ports, a second gate valve connectable to a load-lock module, a pre-aligner device configured to align substrates, the pre-aligner device comprises a third gate valve, a garage configured to temporarily hold a substrate, the garage comprises a fourth gate valve, a robotic arm configured to move substrates between the one or more loading ports and the load-lock module, and a controller configured to delay the opening of the gate valves until the pre-aligner device, garage, or load-lock module is ready to receive a substrate and the robotic arm is available.

In accordance with examples of the disclosure, the controller may determine whether the robotic arm is available, determine, based on the robotic arm being available, whether the pre-aligner device is available, open, based on the pre-aligner device being available, the first gate valve and the third gate valve, move a substrate from a loading port to the pre-aligner device, and close the first gate valve and the third gate valve. In accordance with examples of the disclosure, the controller may determine whether the robotic arm is available, determine, based on the robotic arm being available, whether the load-lock module is available, open, based on the load-lock being available, the second gate valve and one of the third gate valve or the fourth gate valve, move a substrate from the pre-aligner device or the garage to the load-lock module, and close the second gate valve and the open one of the third gate valve or the fourth gate valve. In accordance with examples of the disclosure, the controller may determine whether the robotic arm is available, determine, based on the robotic arm being available, whether the garage is available, open, based on the garage being available, the fourth gate valve and one of the second gate valve or the third gate valve, move a substrate from the pre-aligner device or the load-lock module to the garage, and close the fourth gate valve and the open one of the second gate valve or the third gate valve. In accordance with examples of the disclosure, the controller may determine whether the robotic arm is available, determine, based on the robotic arm being available, whether a loading port is available, open, based on the loading port being available, the first gate valve and one of the second gate valve or the fourth gate valve, move a substrate from the garage or the load-lock module to the loading port, and close the first gate valve and the open one of the second gate valve or the fourth gate valve.

In accordance with examples of the disclosure, an equipment front-end module may comprise a first gate valve connectable to one or more loading ports, a second gate valve connectable to a load-lock module, a first robotic arm configured to move substrates between the one or more loading ports and the load-lock module, an air intake, a dehumidifier comprising an inlet configured to receive ambient air external to the equipment front-end module and an outlet, and a fan configured to move dehumidified air from the dehumidifier outlet to the air intake. The equipment front-end module may include a fan filter unit, located between the fan and the air intake, configured to filter the dehumidified air. The dehumidifier may be a multi-stage dehumidifier comprising cooling coils and a descant wheel. The dehumidified air may have a percent relative humidity of less than 0.6%.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. An apparatus comprising:
a housing defining an interior space;
a first gate valve connectable to a first area atmospherically isolated from the interior space;
a second gate valve connectable to a second area atmospherically isolated from the interior space;
a substrate support plate;
a robotic arm configured to move substrates between the first gate valve, the second gate valve, and the substrate support plate;
a gas inlet; and
a gas outlet,
wherein the gas inlet and the gas outlet are configured to flow a gas across the substrate support plate.

2. The apparatus of claim 1,
wherein the gas is nitrogen gas.

3. The apparatus of claim 1,
wherein the apparatus is an equipment front-end module (EFEM),
wherein the EFEM comprises:
an enclosed chamber with a pre-aligner device configured to align a received substrate, wherein the substrate support plate is inside the pre-aligner device; and
a third gate valve connecting the enclosed chamber to the interior space,
wherein the gas inlet and the gas outlet are in the enclosed chamber,
wherein the robotic arm is further configured to move substrates between one or more loading ports accessible via the first gate valve, a load-lock module accessible via the second gate valve; and the enclosed chamber accessible via the third gate valve, and
wherein the enclosed chamber is configured to flow the gas from the gas inlet toward the gas outlet while the robotic arm transports a substrate through the third gate valve.

4. The apparatus of claim 3,
wherein the gas outlet is located closer to the third gate valve than the gas inlet, and
wherein a gas flow direction of the gas flowed across the substrate support plate is toward the third gate valve.

5. The apparatus of claim 1,
wherein the apparatus is an equipment front-end module (EFEM),
wherein the EFEM comprises:
an enclosed chamber, wherein the substrate support plate is inside the enclosed chamber, and wherein the substrate support plate is a heating plate configured to heat a received substrate or a cooling plate configured to cool the received substrate; and
a third gate valve connecting the enclosed chamber to the interior space,
wherein the gas inlet and the gas outlet are in the enclosed chamber,
wherein the robotic arm is further configured to move substrates between one or more loading ports accessible via the first gate valve, a load-lock module accessible via the second gate valve, and the enclosed chamber accessible via the third gate valve, and
wherein the enclosed chamber is configured to flow the gas from the gas inlet toward the gas outlet while the robotic arm transports a substrate through the third gate valve.

6. The apparatus of claim 5,
wherein the gas outlet is located closer to the third gate valve than the gas inlet, and
wherein a gas flow direction of the gas flowed across the substrate support plate is toward the third gate valve.

7. The apparatus of claim 5, further comprising:
a pre-aligner device configured to align a substrate,
wherein the robotic arm is further configured to move substrates between the one or more loading ports and the pre-aligner device and configured to move aligned substrates between the pre-aligner device and the enclosed chamber.

8. The apparatus of claim 1,
wherein the apparatus is a load-lock module,
wherein the first gate valve is connectable to an equipment front-end module,
wherein the second gate valve connectable to a substrate handling chamber,
wherein the gas outlet is located closer to the first gate valve than the gas inlet, and
wherein the gas inlet and the gas outlet are configured to flow, toward the first gate valve when the first gate valve is open, the gas across the substrate support plate.

9. The apparatus of claim 8,
wherein the first gate valve is configured to permit a robotic arm, from the equipment front-end module, access to the substrate support plate.

10. The apparatus of claim 8,
wherein the second gate valve is configured to permit a robotic arm, from the substrate handling chamber, access to the substrate support plate.

11. An equipment front-end module comprising:
a first gate valve connectable to one or more loading ports;
a second gate valve connectable to a load-lock module;
a pre-aligner device configured to align substrates, wherein the pre-aligner device comprises a third gate valve;
a garage configured to temporarily hold a substrate, wherein the garage comprises a fourth gate valve;
a robotic arm configured to move substrates between the one or more loading ports and the load-lock module; and
a controller configured to delay opening of one of the first gate valve, the second gate valve, the third gate valve, or the fourth gate valve until the pre-aligner device, garage, or load-lock module is ready to receive a substrate and the robotic arm is available.

12. The equipment front-end module of claim 11,
wherein the controller is further configured to:
determine whether the robotic arm is available;
determine, based on the robotic arm being available, whether the pre-aligner device is available;
open, based on the pre-aligner being available, the first gate valve and the third gate valve;
move a substrate from a loading port to the pre-aligner device; and
close the first gate valve and the third gate valve.

13. The equipment front-end module of claim 11,
wherein the controller is further configured to:
determine whether the robotic arm is available;
determine, based on the robotic arm being available, whether the load-lock module is available;
open, based on the load-lock being available, the second gate valve and one of the third gate valve or the fourth gate valve;
move a substrate from the pre-aligner device or the garage to the load-lock module; and
close the second gate valve and the open one of the third gate valve or the fourth gate valve.

14. The equipment front-end module of claim 11,
wherein the controller is further configured to:
determine whether robotic arm is available;
determine, based on the robotic arm being available, whether the garage is available;
open, based on the garage being available, the fourth gate valve and one of the second gate valve or the third gate valve;
move a substrate from the pre-aligner device or the load-lock module to the garage; and
close the fourth gate valve and the open one of the second gate valve or the third gate valve.

15. The equipment front-end module of claim 14,
wherein the controller is further configured to:
determine whether the robotic arm is available;
determine, based on the robotic arm being available, whether a loading port is available;
open, based on the loading port being available, the first gate valve and one of the second gate valve or the fourth gate valve;
move a substrate from the garage or the load-lock module to the loading port; and
close the first gate valve and the open one of the second gate valve or the fourth gate valve.

16. An equipment front-end module comprising:
a first gate valve connectable to one or more loading ports;
a second gate valve connectable to a load-lock module;
a first robotic arm configured to move substrates between the one or more loading ports and the load-lock module;
an air intake;
a dehumidifier comprising an inlet configured to receive ambient air external to the equipment front-end module and an outlet; and
a fan configured to move dehumidified air from the dehumidifier outlet to the air intake.

17. The equipment front-end module of claim 16, further comprising:
a fan filter unit, located between the fan and the air intake, configured to filter the dehumidified air.

18. The equipment front-end module of claim 16,
wherein the dehumidifier is a multi-stage dehumidifier.

19. The equipment front-end module of claim 18,
wherein the multi-stage dehumidifier comprises cooling coils and a descant wheel.

20. The equipment front-end module of claim 18,
wherein the dehumidified air has a percent relative humidity of less than 0.6%.
